(19) United States
(12) Patent Application Publication
(10) Pub. No.: US 2025/0226188 A1
(43) Pub. Date: Jul. 10, 2025

(54) PLASMA ETCHER WITH EDGE RING AND METHOD OF PROCESSING SEMICONDUCTOR DEVICE USING THE SAME

(71) Applicant: Taiwan Semiconductor Manufacturing Company, Ltd., Hsinchu (TW)

(72) Inventor: Ting-Jung Chen, Kaohsiung City (TW)

(73) Assignee: Taiwan Semiconductor Manufacturing Company, Ltd., Hsinchu (TW)

(21) Appl. No.: 18/407,368

(22) Filed: Jan. 8, 2024

(51) Int. Cl. H01J 37/32; H01L 21/3065; H01L 21/683

(52) U.S. Cl. CPC H01J 37/32642; H01J 37/32495; H01J 37/32715; H01L 21/3065; H01L 21/6833; H01J 2237/3341; H01J 2237/3343

(57) ABSTRACT

Provided are a plasma etcher with an edge ring. The edge ring includes a circular lower portion having a lower opening sized to receive an electrostatic chuck supporting a semiconductor device; and a circular upper portion disposed on the circular lower portion, wherein the circular upper portion and the circular lower portion have different materials. The circular lower portion of the edge ring provides electrical and plasma uniformity for the semiconductor device, while the semiconductor device is being processed by the plasma etcher. At mean time, the circular upper portion of the edge ring is configurated to prevent damage of the circular lower portion by the plasma gas.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing equipment are needed. In one example, a plasma processing system is utilized to perform a plasma etching process of a substrate. A plasma etcher, or etching tool, is a tool used in the plasma etching process. A plasma etcher produces a plasma from a process gas (e.g., an oxygen-bearing gas, a fluorine-bearing gas, and/or the like) using a high frequency electric field.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIG. 1 illustrates a top view of a semiconductor device in accordance with some embodiments.

FIG. 2A illustrates a cross-sectional view of a plasma etcher in accordance with some embodiments.

FIG. 2B is an enlarged cross-sectional view of a portion of the plasma etcher illustrated in FIG. 2A.

FIG. 3A to FIG. 3C illustrate cross-sectional views of a semiconductor device with trenches in accordance with various embodiments.

FIG. 4 is a diagram of example components of the plasma etcher of FIG. 2A.

FIG. 5 is a flowchart of an example process for generating a semiconductor device with a plasma etcher and an edge ring.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the Figures The spatially relative terms are intended to encompass different orientations of the device in use or operation in addition to the orientation depicted in the Figures The apparatus may be otherwise oriented (rotated 90 degrees or at other orientations) and the spatially relative descriptors used herein may likewise be interpreted accordingly.

In some instances, a plasma etcher may perform plasma etching to fabricate semiconductor devices. Plasma etching involves a high-speed stream of glow discharge (e.g., a plasma) of an appropriate gas mixture being provided in pulses to a semiconductor device. A plasma source, known as an etch species, can be either charged (e.g., ions) or neutral (e.g., atoms and radicals). During plasma etching, the plasma generates volatile etch products from chemical reactions between elements of a material to be etched and reactive species generated by the plasma. Eventually, atoms of the plasma embed themselves at or just below a surface of a target (e.g., the semiconductor device), thus modifying physical properties of the target.

An edge ring is a component of a plasma etcher that surrounds a semiconductor device provided on an electrostatic chuck of the plasma etcher. An AC voltage is applied on the electrostatic chuck during the etching process. By being electrically biased, the electrostatic chuck not only generates the electrostatic force to hold and support the semiconductor device, but is used as the electrode to help accelerate ions from a plasma sheath towards the semiconductor device in a direction orthogonal to the upper surface of the semiconductor device. However, in the prior art, there is a large potential difference or voltage drop between the edge ring made of quartz and the electrostatic chuck, so that the semiconductor device has uneven surface charges between the central region and the edge region, thereby causing the plasma sheath tends to curve downwards. That is, the plasma sheath has a non-planar curvature at the edge region of the semiconductor device. Such non-planar curvature within the edge region may also be referred to herein as bending or edge tilting of the plasma sheath. When the edge region of the plasma sheath is bending and ions from the plasma enter this edge region, the ions will still be accelerated, but will not be accelerated at an angle that is perpendicular to an upper surface of the semiconductor device. Rather, the ions will be accelerated at an angle that is not perpendicular to the upper surface of the semiconductor device. As such, trenches and/or openings etched into the edge region of the semiconductor device may be formed with non-vertical profiles. In other words, the trenches and/or openings have a tilting angle relative to the vertical sidewall.

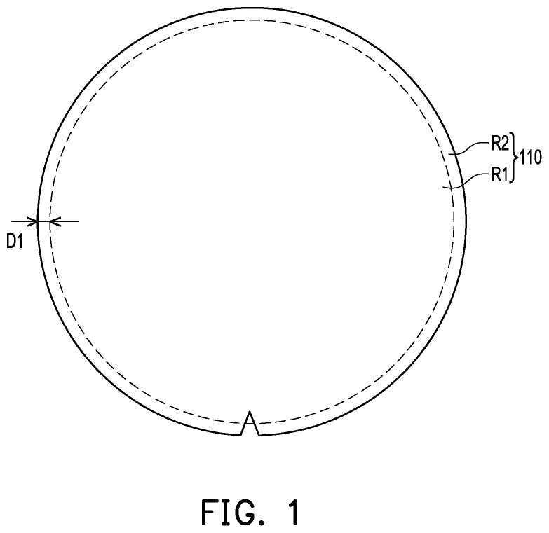

Referring to FIG. 1, there is illustrated a top-down view of a semiconductor device 110. In an embodiment the semiconductor device 110 may be viewed as having a central region R1 and an edge region R2. These regions are indicated as being separate from each other in FIG. 1 by the dashed circle, although no such circle is readily apparent in the actual product. In some embodiments, the semiconductor device 110 includes a silicon substrate having one or more active devices, one or more passive devices, an interconnect structure, or the like thereon. Although other substrates, such as semiconductor-on-insulator (SOI), strained SOL and silicon germanium on insulator, could be used.

In some embodiments, the edge region R2 of the semiconductor device 110 may be a region that is potentially affected by a curvature of an electrical field and the bending plasma sheath during, e.g., an etching process (as stated in the above paragraph). That is, the trenches and/or openings in the edge region R2 have the undesired tilting angle relative to the vertical sidewall. For example, in an embodiment in which the semiconductor device 110 as a whole has a diameter of about 149 mm to about 300 mm, the edge region R2 may have a distance DI of about 0 mm to about 10 mm, or about 3 mm to about 5 mm, such as about 3 mm. Herein, the distance DI of the edge region R2 is referred to the distance extending radially inward from the most edge of the semiconductor device 110.

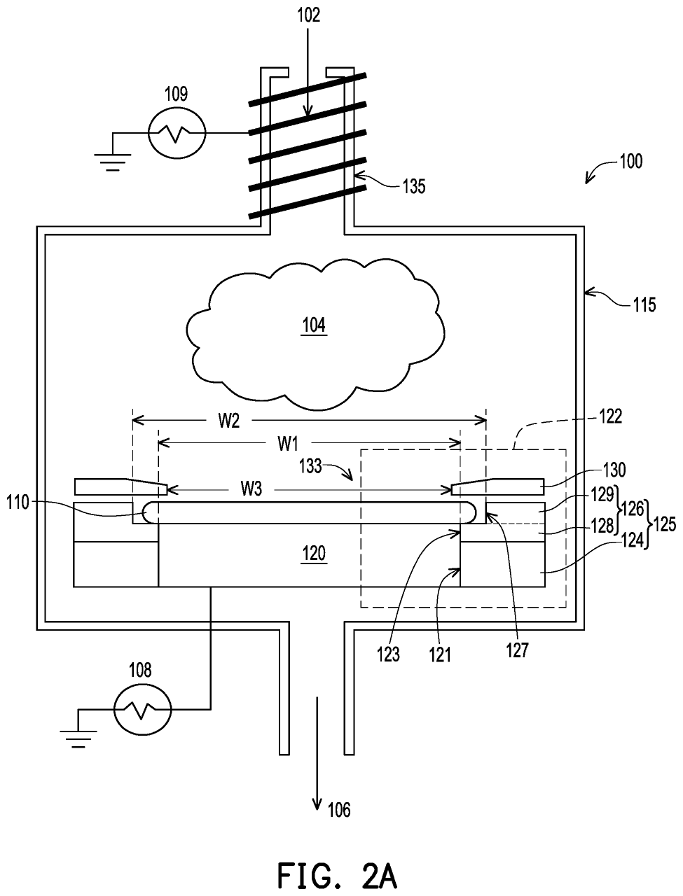

In accordance with some embodiments, an edge ring for a plasma etcher is provided to include a circular lower portion and a circular upper portion on the circular lower portion. The circular upper portion and the circular lower portion may have different materials. In detail, the circular lower portion may have a better electrical conductivity than quartz, so that the electrostatic chuck and the circular lower portion have substantially the same electric potential, thereby increasing the surface charge at the edge region R2 of the semiconductor device and flattening the plasma sheath. On the other hands, the circular upper portion may have a dielectric constant greater than that of the circular lower portion. In such embodiment, the circular upper portion is able to prevent the circular lower portion from exposing to the plasma sheath. That is, the ions of the plasma sheath will be blocked by the circular upper portion to prevent the ions of the plasma sheath from penetrating into the circular lower portion, thereby avoiding the arcing issue. Further details of the edge ring are provided below in connection with FIG. 2A and FIG. 2B.

FIG. 2A illustrates a cross-sectional view of a plasma etcher 100 in accordance with some embodiments. FIG. 2B is an enlarged cross-sectional view of a portion 122 of the plasma etcher 100 illustrated in FIG. 2A.

Referring to FIG. 2A and FIG. 2B, the plasma etcher 100 may process the semiconductor device 110 and may include a chamber 115, an electrostatic chuck (ESC) 120, an edge ring 125, a bevel shielding ring 130, and a plasma gas inlet 135.

The plasma etcher 100 is a semiconductor processing tool that removes materials from a surface of semiconductor device 110. In some embodiments, a portion of semiconductor device 110 is protected from an etchant by a masking material that resists etching. For example, the masking material may include a photoresist that is patterned using photolithography. The plasma etcher 100 may perform a dry (e.g., plasma) etching process on the semiconductor device 110. In the present embodiment, the dry (e.g., plasma) etching process is performed on the semiconductor device 110 to form a plurality of trenches 112, 114 in a substrate of the semiconductor device 110, as shown in FIG. 2A. The plasma etching process may operate in several modes based on adjusting parameters of the plasma. The plasma produces energetic free radicals, that are neutrally charged and that react at a surface of the semiconductor device 110. Plasma etching may be isotropic (e.g., exhibiting a lateral undercut rate on a patterned surface approximately the same as a downward etch rate) or anisotropic (e.g., exhibiting a smaller lateral undercut rate than the downward etch rate).

The chamber 115 may include a chamber to accommodate a plasma gas 104 and to process the semiconductor device 110 with the plasma gas 104. The chamber 115 may be sized and shaped depending on a size and a shape of the semiconductor device 110 to be processed by the plasma etcher 100. The chamber 115 may be box-shaped to aid in the plasma etching process, but may be other shapes, such as cylindrical, spherical, and/or the like. In some embodiments, the chamber 115 is constructed of a material or materials that are resistant to abrasion and/or corrosion caused by materials used to generate the plasma. For example, the chamber 115 may be constructed of a metal, such as aluminum, stainless steel, and/or the like. In some embodiments, the chamber 115 includes walls with thicknesses that provide a rigid structure capable of supporting components within the chamber 115 and of containing the plasma gas 104 under pressure.

The electrostatic chuck 120 may include a component that generates an attracting force between electrostatic chuck 120 and the semiconductor device 110 based on a voltage applied to electrostatic chuck 120. The voltage may be provided from a power supply 108 that provides a high bias voltage to electrostatic chuck 120. The attractive force may cause the semiconductor device 110 to be retained on and supported by the electrostatic chuck 120, during processing of the semiconductor device 110. The electrostatic chuck 120 may be sized and shaped depending on a size and a shape of the semiconductor device 110 to be processed by the plasma etcher 100. For example, the electrostatic chuck 120 may be circular shaped and may support all or a portion of a circular shaped the semiconductor device 110. In some embodiments, the electrostatic chuck 120 is constructed of a material or materials that are resistant to abrasion and/or corrosion caused by materials used to generate the plasma, and that can generate the attractive force between electrostatic chuck 120 and the semiconductor device 110. For example, the electrostatic chuck 120 may be constructed of a metal, such as aluminum, stainless steel, and/or the like. In the present embodiment, the electrostatic chuck 120 is made from anodized aluminum, which is aluminum that has been treated to form a surface layer of Al₂O₃.

The edge ring 125 may include a component that surrounds the semiconductor device 110 provided on electrostatic chuck 120 of the plasma etcher 100. Specifically, the edge ring 125 may a circular lower portion 124 and a circular upper portion 126 disposed on the circular lower portion 124. The circular lower portion 124 may have a lower opening 121 sized to receive the electrostatic chuck 120. In some embodiments, the circular lower portion 124 may be adjacent to and be in direct contact with the sidewall of the electrostatic chuck 120, so that a physical interface is included between the circular lower portion 124 and the electrostatic chuck 120. In some alternative embodiments, the circular lower portion 124 and the electrostatic chuck 120 are integrally formed and no physical interface is included between the circular lower portion 124 and the electrostatic chuck 120. In addition, the circular upper portion 126 may include a first portion 128 and a second portion 129 disposed on the first portion 128. The first portion 128 may be adjacent to and be in direct contact with the sidewall of the electrostatic chuck 120, so that a physical interface is included between the first portion 128 and the electrostatic chuck 120. On the other hand, the second portion 129 may be adjacent to the semiconductor device 110 and spaced from the semiconductor device 110 by a non-zero distance. That is, a gap is between the second portion 129 and the semiconductor device 110, so that the plasma gas 104 may extend between the second portion 129 and the semiconductor device 110 along the gap. The first portion 128 may have a first opening 123 sized to receive the electrostatic chuck 120. The second portion 129 may have a second opening 127 sized to receive the semiconductor device 110. In some embodiments, the second opening 127 has a lateral width W2 substantially greater than a lateral width W1 of the first opening 123.

The bevel shielding ring 130 may be disposed over the edge ring 125 and further cover an edge 118 of the semiconductor device 110, as shown in FIG. 2B. In some embodiments, the bevel shielding ring 130 is sized and shaped based on a size and a shape of the plasma etcher 100, a size and a shape of the semiconductor device 110 processed by the plasma etcher 100, and/or the like. For example, the bevel shielding ring 130 may be circular shaped and may cover the edge 118 of the semiconductor device 110 to prevent erosion of the thinner edge 118 of the semiconductor device 110 and further avoid the chipping issue. In some embodiments, the laterally width of the edge 118 of the semiconductor device 110 may be 0.7 mm to 1.8 mm, which is less than the distance DI of the edge region R2 (FIG. 1). On the other hand, the bevel shielding ring 130 may include an opening 133 (FIG. 2A) to enable the plasma 104 to reach the surface of the semiconductor device 110. In some embodiments, the laterally width W3 of the opening 133 is less than the lateral width W1 of the first opening 123 and the lateral width W2 of the second opening 127. In some embodiments, the bevel shielding ring 130 is constructed of a material or materials that are resistant to abrasion and/or corrosion caused by materials used to generate the plasma, and that can prevent the erosion of the thinner edge 118 of the semiconductor device 110. For example, the bevel shielding ring 130 may be constructed of a metal oxide, such as aluminum oxide (Al₂O₃).

In detail, as shown in FIG. 2B, the bevel shielding ring 130 may include a main portion 132 and a chamfer portion 134. The main portion 132 may be disposed over the edge ring 125. The chamfer portion 134 may be disposed over the edge 118 of the semiconductor device 110 and have an inner surface 136. The inner surface 136 may be angled along a direction from the semiconductor device 110 toward the edge ring 125. In the present embodiment, the tilted or angled inner surface 136 can allow the shape of the plasma sheath 116 at the edge 118 approximate consistent with the shape of the plasma sheath 116 at the central region R1 to provide the plasma uniformity for the semiconductor device 110. In some embodiments, the chamfer portion 134 may have a thickness T4 of about 0.1 mm to about 0.5 mm at the thinnest region, while the main portion 132 may have an average thickness T5 of about 0.5 cm to about 1.0 mm. The thicker thickness T5 can provide the better operability, and the thinner thickness T4 can provide the better plasma uniformity.

Referring back to FIG. 2A, the plasma gas inlet 135 may include an opening in the chamber 115 that permits a process gas 102 to be provided to the chamber 115. The process gas 102 may be a source gas for the plasma 104 that includes small molecules rich in chlorine or fluorine. For example, carbon tetra fluorine may be utilized as the plasma gas to etch silicon and chlorine may be utilized as the plasma gas to etch aluminum, trifluoro methane may be used to etch silicon dioxide and silicon nitride, and/or the like. The process gas 102 may also include oxygen that is used to oxidize a photoresist and facilitate removal of the photoresist. In some embodiments, the process gas 102 is converted to the plasma 104 based on applying a high frequency electric field (e.g., provided by a power supply 109) to the process gas 102 via the plasma gas inlet 135.

In operation, the plasma etcher 100 may produce the plasma 104 from the process gas 102 using the high frequency electric field. The semiconductor device 110 may be placed in the plasma etcher 100, and air may be evacuated from the chamber 115 using one or more vacuum pumps 106. The process gas 102 may be introduced at low pressure into the chamber 115 via plasma gas inlet 135. The process gas 102 may be excited into the plasma 104 through dielectric breakdown. The plasma 104 may produce energetic free radicals, that are neutrally charged and that react at the surface of the semiconductor device 110 and etch the surface. The plasma etching may be isotropic (e.g., exhibiting a lateral undercut rate on a patterned surface approximately the same as a downward etch rate) or anisotropic (e.g., exhibiting a smaller lateral undercut rate than the downward etch rate).

In addition, a voltage is provided from the power supply 108 to electrostatic chuck 120 during the etching process (e.g., during providing the plasma 104 to the semiconductor device 110). In the present embodiment, the voltage is an alternating current (AC) voltage. However, any suitable voltages may be used. By being electrically biased, the electrostatic chuck 120 not only generates the electrostatic force to hold and support the semiconductor device 110, but is used as the electrode to help accelerate ions from the plasma sheath 116 towards the semiconductor device 110 in a direction 105 orthogonal to the upper surface of the semiconductor device 110.

It should be noted that, in the present embodiment, the circular upper portion 126 and the circular lower portion 124 have different materials. Specifically, a dielectric constant of the circular upper portion 126 is substantially greater than a dielectric constant of the circular lower portion 124, and an electrical conductivity of the circular lower portion 124 is substantially greater than an electrical conductivity of the circular upper portion 126. For example, the circular lower portion 124 may be made from anodized aluminum which is aluminum that has been treated to form a surface layer of Al₂O₃, while the circular upper portion 126 may be made from silicon carbide (SIC). When the bias voltage is provided from the power supply 108 to electrostatic chuck 120, the electrostatic chuck 120 and the circular lower portion 124 of the edge ring 125 may have substantially the same electric potential due to the good electrical conductivity of the circular lower portion 124. In this case, the bias voltage at the central region R1 and the edge region R2 may be regarded as the same, so that a thickness 116d1 of the plasma sheath 116 at the central region R1 is the same as a thickness 116d2 of the plasma sheath 116 at the edge region R2. That is, a distance 116d1 measured from the bottom surface of the plasma 104 to the top surface of the semiconductor device 110 at the central region R1 is the same as a distance 116d2 measured from the bottom surface of the plasma 104 to the top surface of the semiconductor device 110 at the edge region R2. As a result, the circular lower portion 124 can be utilized during the etching process to help flatten the plasma sheath 116 over the edge region R2 of the semiconductor device 110. Additionally, the circular upper portion 126 made from the high dielectric constant material can accumulate more electrons to increase the surface charge at the edge region R2, thereby further flattening the plasma sheath 116 over the edge region R2 of the semiconductor device 110. In this case, the flattened plasma sheath 116 over the edge region R2 of the semiconductor device 110 can help accelerate the ions from the plasma sheath 116 in a direction 105 orthogonal to the upper surface of the semiconductor device 110, even in the edge region R2 of the semiconductor device 110. As such, the trenches 114 etched into the edge region R2 of the semiconductor device 110 are formed with more vertical profiles.

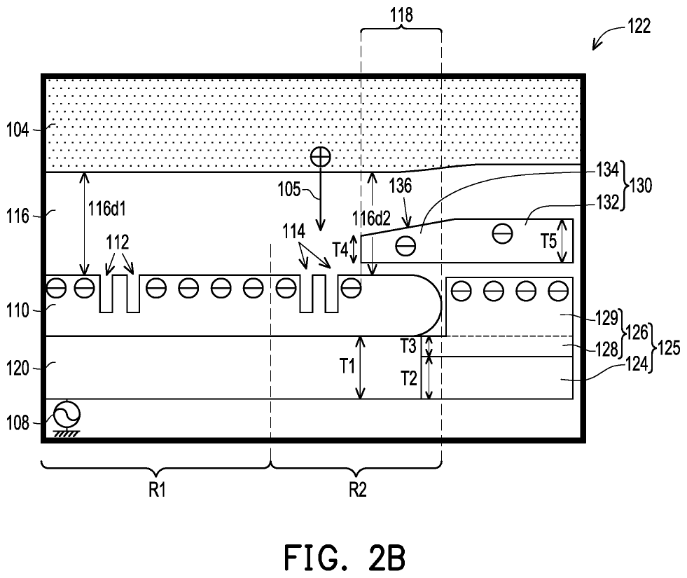

By the flattened plasma sheath 116, the trenches 112 at the central region R1 and the trenches 114 at the edge region R2 may be formed with similar and vertical profiles. Specifically, as shown in FIG. 3A, the trenches 112 at the central region R1 may have a depth 112d, a width 112w, an aspect ratio (112d/112w) of between about 30 to 40, and a first tilting angle θ1 of about 90°. Similarly, the trenches 114A at the edge region R2 may have the same aspect ratio as the trenches 112, and a second tilting angle θ2 of about 90°. In this case, the trenches from central region R1 to the edge region R2 may have uniform critical dimension and vertical profile to improve the circuit probing (CP) yield of the semiconductor device. In the present embodiment, the CP yield of the semiconductor device 110 at the edge region R2 of 3 nm to 5 mm can be improved from 43% to 98% compared with the conventional technology.

In some embodiments, the tilting angle of the trenches 114 in the edge region R2 can be adjusted by various process parameters, such as the bias voltage, the thickness variation of the circular lower portion 124, or the like. For example, when the bias voltage applied to the electrostatic chuck 120 increases, the plasma sheath 116 becomes flatter and the trenches 114 formed in the edge region R2 have more vertical profiles. In addition, when a thickness T2 of the circular lower portion 124 increases, the plasma sheath 116 becomes flatter and the trenches 114 formed in the edge region R2 have more vertical profiles. The thickness T2 of the circular lower portion 124 may be less than a thickness T1 of the electrostatic chuck 120, and the first portion 128 of the circular upper portion 126 may have a thickness T3 of at least 0.3 mm, as shown in FIG. 2B. In some embodiments, the thickness T1 of the electrostatic chuck 120 may be about 2 cm to about 5 cm, the thickness T2 of the circular lower portion 124 may be about 2 cm to about 5 cm, the thickness T3 of the first portion 128 of the circular upper portion 126 may be about 3 mm to about 10 mm, and a ratio (T2/T3) of the thickness T2 to the thickness T3 may be about 8 to 1. However, the disclosure is not limited thereto, in some alternative embodiments, the trenches 114B at the edge region R2 may have a third tilting angle θ3 of about 90° to 95°, as shown in FIG. 3B. In some other embodiments, the trenches 114C at the edge region R2 may be adjusted to have a fourth tilting angle θ4 of about 85° to 90°, as shown in FIG. 3C. As such, it is submitted that a ratio of the tilting angle of the trenches 112 at the central region R1 to the tilting angle of the trenches 114 at the edge region R2 may be about 90:85 to about 90:95.

Referring back to FIG. 2B, the circular upper portion 126 may completely cover the top surface of the circular lower portion 124. Specifically, the first portion 128 of the circular upper portion 126 may have enough thickness T3 to completely cover and protect the top surface of the circular lower portion 124 form exposing to the plasma sheath 116. That is, the ions of the plasma sheath 116 will be blocked by the circular upper portion 126 to prevent the ions of the plasma sheath 116 from penetrating into the circular lower portion 124, thereby avoiding the arcing issue.

In some embodiments, the circular lower portion 124 of the edge ring 125 is constructed of a material or materials that can provide the electrical and plasma uniformity for the semiconductor device 110. For example, the circular lower portion 124 may be constructed of anodized aluminum, a metal, such as aluminum, stainless steel, and/or the like. In some embodiments, the circular upper portion 126 of the edge ring 125 is constructed of a material or materials that are resistant to abrasion and/or corrosion caused by materials used to generate the plasma 104. For example, the circular upper portion 126 may be constructed of a high-k dielectric material which has the dielectric constant greater than quartz, such as silicon carbide (SiC), silicon nitride (SiN), or a combination thereof.

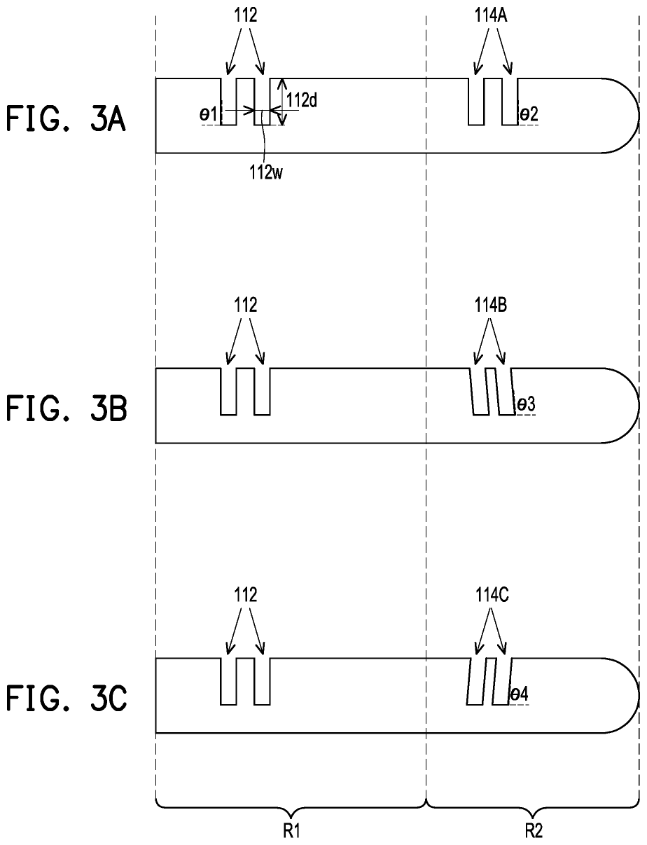

FIG. 4 is a diagram of example components of a device 400, which may correspond to the plasma etcher 100. In some embodiments, the plasma etcher 100 may include one or more devices 400 and/or one or more components of device 400. As shown in FIG. 4, the device 400 may include a bus 410, a processor 420, a memory 430, a storage component 440, an input component 450, an output component 460, and a communication component 470.

The bus 410 includes a component that enables wired and/or wireless communication among the components of the device 400. The processor 420 includes a central processing unit, a graphics processing unit, a microprocessor, a controller, a microcontroller, a digital signal processor, a field-programmable gate array, an application-specific integrated circuit, and/or another type of processing component. The processor 420 is implemented in hardware, firmware, or a combination of hardware and software. In some embodiments, the processor 420 includes one or more processors capable of being programmed to perform a function. The memory 430 includes a random-access memory), a read only memory, and/or another type of memory (e.g., a flash memory, a magnetic memory, and/or an optical memory).

The storage component 440 stores information and/or software related to the operation of the device 400. For example, the storage component 440 may include a hard disk drive, a magnetic disk drive, an optical disk drive, a solid state disk drive, a compact disc, a digital versatile disc, and/or another type of non-transitory computer-readable medium. The input component 450 enables the device 400 to receive input, such as user input and/or sensed inputs. For example, the input component 450 may include a touch screen, a keyboard, a keypad, a mouse, a button, a microphone, a switch, a sensor, a global positioning system component, an accelerometer, a gyroscope, an actuator, and/or the like. The output component 460 enables the device 400 to provide output, such as via a display, a speaker, and/or one or more light-emitting diodes. The communication component 470 enables the device 400 to communicate with other devices, such as via a wired connection and/or a wireless connection. For example, the communication component 470 may include a receiver, a transmitter, a transceiver, a modem, a network interface card, an antenna, and/or the like.

The device 400 may perform one or more processes described herein. For example, a non-transitory computer-readable medium (e.g., the memory 430 and/or the storage component 440) may store a set of instructions (e.g., one or more instructions, code, software code, program code, and/or the like) for execution by the processor 420. The processor 420 may execute the set of instructions to perform one or more processes described herein. In some embodiments, execution of the set of instructions, by one or more processors 420, causes the one or more processors 420 and/or the device 400 to perform one or more processes described herein. In some embodiments, hardwired circuitry may be used instead of or in combination with the instructions to perform one or more processes described herein. Thus, implementations described herein are not limited to any specific combination of hardware circuitry and software.

The number and arrangement of components shown in FIG. 4 are provided as an example. The device 400 may include additional components, fewer components, different components, or differently arranged components than those shown in FIG. 4. Additionally, or alternatively, a set of components (e.g., one or more components) of the device 400 may perform one or more functions described as being performed by another set of components of the device 400.

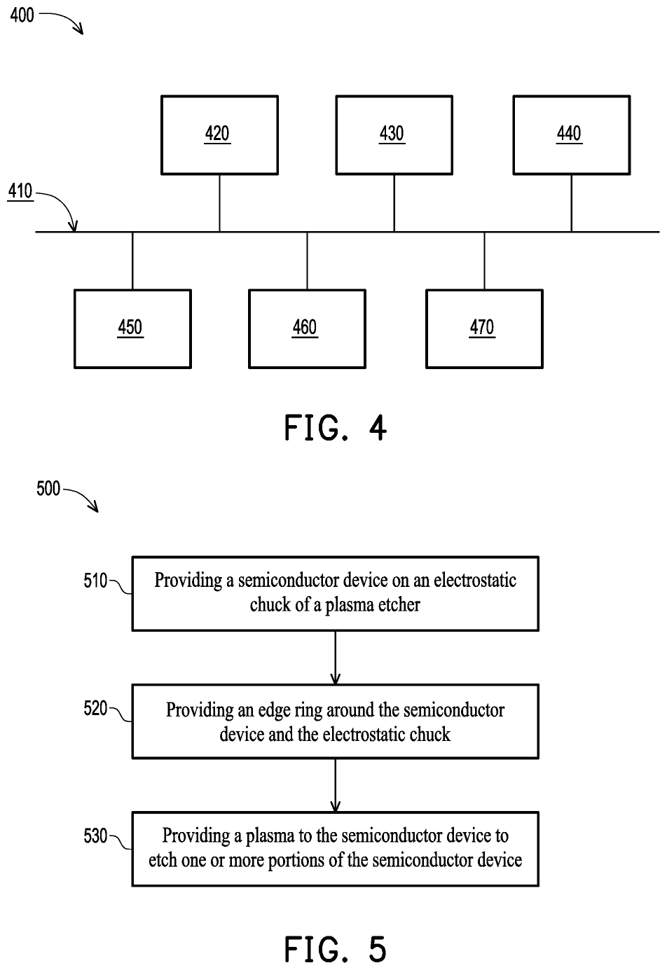

FIG. 5 is a flowchart of an example process 500 for generating a semiconductor device (e.g., the semiconductor device described herein and/or other types of semiconductor devices) with a plasma etcher and a combo edge ring with different materials. In some embodiments, one or more process blocks of FIG. 5 may be performed by a device (e.g., the plasma etcher 100). In some embodiments, one or more process blocks of FIG. 5 may be performed by another device or a group of devices separate from or including the device. Additionally, or alternatively, one or more process blocks of FIG. 5 may be performed by one or more components of the device 400, such as the processor 420, the memory 430, the storage component 440, the input component 450, the output component 460, the communication interface 470, and/or the like.

As shown in FIG. 5, the process 500 may include providing a semiconductor device on an electrostatic chuck of the plasma etcher (block 510). For example, the semiconductor device 110 may be provided on the electrostatic chuck 120 of the plasma etcher 100, as described above.

As further shown in FIG. 5, the process 500 may include providing an edge ring around the semiconductor device and the electrostatic chuck (block 520). For example, the edge ring 125 may be provided around the semiconductor device 110 and the electrostatic chuck 120, as described above. In some embodiments, the edge ring 125 includes a circular lower portion 124 and a circular upper portion 126 on the circular lower portion 124. The circular upper portion 126 and the circular lower portion 124 may have different materials. Specifically, a dielectric constant of the circular upper portion 126 is substantially greater than a dielectric constant of the circular lower portion 124, and an electrical conductivity of the circular lower portion 124 is substantially greater than an electrical conductivity of the circular upper portion 126. The combo edge ring 125 with different materials can flatten the plasma sheath 116 over the edge region R2, so that the trenches 114 etched into the edge region R2 of the semiconductor device 110 are formed with more vertical profiles. As such, the trenches from central region R1 to the edge region R2 may have uniform critical dimension and vertical profile to improve the CP yield of the semiconductor device 110.

As further shown in FIG. 5, the process 500 may include providing a plasma to the semiconductor device to etch one or more portions of the semiconductor device (block 530). For example, a plasma 104 may be provided to the semiconductor device 110, as described above. In some embodiments, the plasma 104 etches one or more portions of the semiconductor device 110. For example, the plasma 104 etches a substrate of the semiconductor device 110 to form a plurality of trenches 112, 114 in the substrate of the semiconductor device 110. However, the disclosure is not limited thereto, in some other embodiments, the plasma 104 etches any films and layers to form various patterns and devices of the semiconductor device.

The process 500 may include additional implementations, such as any single implementation or any combination of implementations described below and/or in connection with one or more other processes described elsewhere herein.

Although FIG. 5 shows example blocks of the process 500, in some embodiments, the process 500 may include additional blocks, fewer blocks, different blocks, or differently arranged blocks than those depicted in FIG. 5. Additionally, or alternatively, two or more of the blocks of the process 500 may be performed in parallel.

In this way, the design of edge ring can facilitate to flatten the plasma sheath, so that the trenches from central region to the edge region may have uniform critical dimension and vertical profile, thereby improving the CP yield of the semiconductor device.

In accordance with an embodiment, an edge ring for a plasma etcher includes a circular lower portion having a lower opening sized to receive an electrostatic chuck supporting a semiconductor device; and a circular upper portion disposed on the circular lower portion. The circular upper portion and the circular lower portion have different materials.

In some embodiments, the circular upper portion includes a first portion having a first opening sized to receive the electrostatic chuck; and a second portion disposed on the first portion and having a second opening, the second opening sized to receive the semiconductor device, wherein a lateral width of the second opening is substantially greater than a lateral width of the first opening. In some embodiments, the first portion is in contact with a sidewall of the electrostatic chuck and completely covers a top surface of the circular lower portion. In some embodiments, a dielectric constant of the circular upper portion is substantially greater than a dielectric constant of the circular lower portion. In some embodiments, an electrical conductivity of the circular lower portion is substantially greater than an electrical conductivity of the circular upper portion. In some embodiments, a material of the circular lower portion is anodized aluminum, and a material of the circular upper portion is silicon carbide (SIC).

In accordance with an embodiment, a method of processing a semiconductor device with a plasma etcher includes providing the semiconductor device on an electrostatic chuck of the plasma etcher; providing an edge ring around the semiconductor device and the electrostatic chuck; and providing a plasma to the semiconductor device to etch one or more portions of the semiconductor device. The edge ring includes a circular lower portion; and a circular upper portion disposed on the circular lower portion. The circular upper portion and the circular lower portion have different materials, and the circular upper portion is configurated to prevent damage of the circular lower portion based on utilization of the plasma etcher.

In some embodiments, the method further includes providing a bias voltage to the electrostatic chuck and the edge ring while the plasma is provided to the semiconductor device. In some embodiments, the electrostatic chuck and the circular lower portion of the edge ring have substantially the same electric potential. In some embodiments, the circular lower portion of the edge ring is configured to level a plasma sheath over a central region of the semiconductor device with a plasma sheath over an edge region of the semiconductor device. In some embodiments, the circular upper portion includes a first portion having a first opening sized to receive the electrostatic chuck; and a second portion disposed on the first portion and having a second opening, the second opening sized to receive the semiconductor device, wherein a lateral width of the second opening is substantially greater than a lateral width of the first opening. In some embodiments, the etching the one or more portions of the semiconductor device includes forming a plurality of trenches in a substrate of the semiconductor device, wherein a ratio of a first tilting angle of the plurality of trenches at a central region of the semiconductor device to a second tilting angle of the plurality of trenches at an edge region of the semiconductor device is between 90:85 and 90:95. In some embodiments, a thickness variation of the circular lower portion is configured to adjust the second tilting angle of the plurality of trenches at the edge region of the semiconductor device. In some embodiments, a dielectric constant of the circular upper portion is substantially greater than a dielectric constant of the circular lower portion. In some embodiments, an electrical conductivity of the circular lower portion is substantially greater than an electrical conductivity of the circular upper portion.

In accordance with an embodiment, a plasma etcher includes a chamber; a plasma gas inlet attached to the chamber and to receive a plasma gas; an electrostatic chuck provided in the chamber and to support a semiconductor device; and an edge ring provided in the chamber and to surround the electrostatic chuck and the semiconductor device. The edge ring includes a circular lower portion; and a circular upper portion disposed on the circular lower portion. The circular upper portion completely covers a top surface of the circular lower portion, and the circular upper portion is configurated to prevent erosion of the circular lower portion by the plasma gas.

In some embodiments, a dielectric constant of the circular upper portion is substantially greater than a dielectric constant of the circular lower portion. In some embodiments, an electrical conductivity of the circular lower portion is substantially greater than an electrical conductivity of the circular upper portion. In some embodiments, the plasma etcher further includes a bevel shielding ring is configurated to prevent erosion at an edge of the semiconductor device by the plasma gas. In some embodiments, the bevel shielding ring includes a chamfer portion that is disposed over the edge of the semiconductor device, wherein the chamfer portion includes an inner surface that is angled along a direction from the semiconductor device toward the edge ring to provide the plasma uniformity for the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An edge ring for a plasma etcher, the edge ring comprising:
a circular lower portion having a lower opening sized to receive an electrostatic chuck supporting a semiconductor device; and
a circular upper portion disposed on the circular lower portion, wherein the circular upper portion and the circular lower portion have different materials.

2. The edge ring of claim 1, wherein the circular upper portion comprises:
a first portion having a first opening sized to receive the electrostatic chuck; and
a second portion disposed on the first portion and having a second opening, the second opening sized to receive the semiconductor device, wherein a lateral width of the second opening is substantially greater than a lateral width of the first opening.

3. The edge ring of claim 2, wherein the first portion is in contact with a sidewall of the electrostatic chuck and completely covers a top surface of the circular lower portion.

4. The edge ring of claim 1, wherein a dielectric constant of the circular upper portion is substantially greater than a dielectric constant of the circular lower portion.

5. The edge ring of claim 1, wherein an electrical conductivity of the circular lower portion is substantially greater than an electrical conductivity of the circular upper portion.

6. The edge ring of claim 1, wherein a material of the circular lower portion is anodized aluminum, and a material of the circular upper portion is silicon carbide (SiC).

7. A method of processing a semiconductor device with a plasma etcher, the method comprising:
providing the semiconductor device on an electrostatic chuck of the plasma etcher;
providing an edge ring around the semiconductor device and the electrostatic chuck, wherein the edge ring comprises:
a circular lower portion; and
a circular upper portion disposed on the circular lower portion, wherein the circular upper portion and the circular lower portion have different materials, and the circular upper portion is configurated to prevent damage of the circular lower portion based on utilization of the plasma etcher; and
providing a plasma to the semiconductor device to etch one or more portions of the semiconductor device.

8. The method of claim 7, further comprising providing a bias voltage to the electrostatic chuck and the edge ring while the plasma is provided to the semiconductor device.

9. The method of claim 8, wherein the electrostatic chuck and the circular lower portion of the edge ring have substantially the same electric potential.

10. The method of claim 8, wherein the circular lower portion of the edge ring is configured to level a plasma sheath over a central region of the semiconductor device with a plasma sheath over an edge region of the semiconductor device.

11. The method of claim 7, wherein the circular upper portion comprises:
a first portion having a first opening sized to receive the electrostatic chuck; and
a second portion disposed on the first portion and having a second opening, the second opening sized to receive the semiconductor device, wherein a lateral width of the second opening is substantially greater than a lateral width of the first opening.

12. The method of claim 11, wherein etching the one or more portions of the semiconductor device comprises:
forming a plurality of trenches in a substrate of the semiconductor device, wherein a ratio of a first tilting angle of the plurality of trenches at a central region of the semiconductor device to a second tilting angle of the plurality of trenches at an edge region of the semiconductor device is between 90:85 and 90:95.

13. The method of claim 12, wherein a thickness variation of the circular lower portion is configured to adjust the second tilting angle of the plurality of trenches at the edge region of the semiconductor device.

14. The method of claim 7, wherein a dielectric constant of the circular upper portion is substantially greater than a dielectric constant of the circular lower portion.

15. The method of claim 7, wherein an electrical conductivity of the circular lower portion is substantially greater than an electrical conductivity of the circular upper portion.

16. A plasma etcher, comprising:
a chamber;
a plasma gas inlet attached to the chamber and to receive a plasma gas;
an electrostatic chuck provided in the chamber and to support a semiconductor device; and
an edge ring provided in the chamber and to surround the electrostatic chuck and the semiconductor device, wherein the edge ring comprises:
a circular lower portion; and
a circular upper portion disposed on the circular lower portion, wherein the circular upper portion completely covers a top surface of the circular lower portion, and the circular upper portion is configurated to prevent erosion of the circular lower portion by the plasma gas.

17. The plasma etcher of claim 16, wherein a dielectric constant of the circular upper portion is substantially greater than a dielectric constant of the circular lower portion.

18. The plasma etcher of claim 16, wherein an electrical conductivity of the circular lower portion is substantially greater than an electrical conductivity of the circular upper portion.

19. The plasma etcher of claim 16, further comprising a bevel shielding ring is configurated to prevent erosion at an edge of the semiconductor device by the plasma gas.

20. The plasma etcher of claim 19, wherein the bevel shielding ring comprises:
a chamfer portion that is disposed over the edge of the semiconductor device, wherein the chamfer portion includes an inner surface that is angled along a direction from the semiconductor device toward the edge ring to provide the plasma uniformity for the semiconductor device.
